(19) United States
(12) Patent Application Publication
(10) Pub. No.: US 2010/0327248 A1
(43) Pub. Date: Dec. 30, 2010

(54) CELL PATTERNING WITH MULTIPLE HARD MASKS

(75) Inventors: Antoine Khoueir, Apple Valley, MN (US); Shuiyuan Huang, Apple Valley, MN (US); Andrew Habermas, Bloomington, MN (US); Helena Stadniychuk, Eagan, MN (US); Ivan P. Ivanov, Apple Valley, MN (US); Yongchul Ahn, Eagan, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/493,281

(22) Filed: Jun. 29, 2009

(51) Int. Cl. H01L 47/00

(52) U.S. Cl. 257/2; 438/3; 438/478; 257/E47.001; 257/E47.005

(57) ABSTRACT

A method of making a memory cell or magnetic element by using two hard masks. The method includes first patterning a second hard mask to form a reduced second hard mask, with a first hard mask being an etch stop for the patterning process, and then patterning the first hard mask to form a reduced first hard mask by using the reduced second hard mask as a mask and using an etch stop layer as an etch stop. After patterning both hard masks, then patterning a functional layer by using the reduced first hard mask as a mask. In the resulting memory cell, the first hard mask layer is also a top lead, and the diameter of the first hard mask layer is at least essentially the same as the diameter of the etch stop layer, the adhesion layer, and the functional layer.

### BACKGROUND

Fast growth of the pervasive computing and handheld/communication industry has generated exploding demand for high capacity nonvolatile solid-state data storage devices and rotating magnetic data storage device. Current technology like flash memory has several drawbacks such as slow access speed, limited endurance, and the integration difficulty. Flash memory (NAND or NOR) also faces scaling problems. Also, traditional rotating storage faces challenges in areal density and in making components like reading/recording heads smaller and more reliable.

Resistive sense memories (RSM) are promising candidates for future nonvolatile and universal memory by storing data bits as either a high or low resistance state. One such memory, magnetic random access memory (MRAM), features non-volatility, fast writing/reading speed, almost unlimited programming endurance and zero standby power. The basic component of MRAM is a magnetic tunneling junction (MTJ). MRAM switches the MTJ resistance by using a current induced magnetic field to switch the magnetization of MTJ. As the MTJ size shrinks, the switching magnetic field amplitude increases and the switching variation becomes more severe. Another such memory, resistive random access memory (RRAM), stores data bits based on resistance in the cell. For example, the resistance may be based on the presence or absence of a conducting filament, or by the phase (i.e., crystalline or amorphous) of the cell material.

There are desires to improve the manufacturing processes of cells for resistive sense memories and similar uses.

### BRIEF SUMMARY

The present disclosure relates to methods of making cells including sensors and memory cells, such as magnetic tunnel junction cells and other cells for spin torque random access memory (ST RAM), and cells for resistive random access memory (RRAM). The methods include utilizing multiple hard masks during the patterning process.

In one particular embodiment, this disclosure provides a method of making a magnetic cell by first forming a starting stack comprising a substrate, a functional layer, an etch stop layer, a first hard mask and a second hard mask, with the functional layer between the substrate and the etch stop layer and the first hard mask between the etch stop layer and the second hard mask, on a side opposite the functional layer. The method includes patterning the second hard mask to form a reduced second hard mask, with the first hard mask being a first etch stop for the patterning process, and then patterning the first hard mask to form a reduced first hard mask by using the reduced second hard mask as a first mask and using the etch stop layer as a second etch stop. The method also includes patterning the functional layer by using the reduced first hard mask as a second mask.

In another particular embodiment, this disclosure provides a resistive sense memory cell comprising a bottom lead, a memory layer for storing more than one magnetic or resistive state and an etch stop layer, with the memory layer between the etch stop layer and the bottom lead. Also includes is an adhesion layer between the etch stop layer and the memory layer, and a hard mask layer on the etch stop layer opposite the adhesion layer. The diameter of the hard mask layer is at least essentially the same as the diameter of the etch stop layer, the adhesion layer, and the memory layer. The hard mask layer is the top lead for the cell.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a cross-sectional schematic diagram of an illustrative magnetic cell;

FIG. 2 is a cross-section schematic diagram of an illustrative resistive cell;

FIGS. 3A-3F are schematic, step wise illustrations of a method for patterning a cell stack; and

FIG. 4 is a schematic illustration of an alternate step from a method for patterning a cell stack.

The figures are not necessarily to scale, nor are individual elements within the figures in a relative scale. Like numbers used in the figures refer to like components. However, it will be understood that the use of a number to refer to a component in a given figure is not intended to limit the component in another figure labeled with the same number.

### DETAILED DESCRIPTION

This disclosure is directed to memory cells (e.g., resistive memory or magnetic memory) or magnetic sensors and methods of making those cells or sensors. In some embodiments, the sensor is a magnetic read sensor such as a magnetic read sensor used in a rotating magnetic storage device. In other embodiments, the cell is a memory cell and may be referred to as a magnetic memory cell, magnetic tunnel junction cell (MTJ), variable resistive memory cell, variable resistance memory cell, or resistive sense memory (RSM) cell or the like.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

It is noted that terms such as “top”, “bottom”, “above, “below”, etc. may be used in this disclosure. These terms should not be construed as limiting the position or orientation of a structure, but should be used as providing spatial relationship between the structures.

The present disclosure is directed to methods of making memory cells and sensors, the methods including a utilizing multiple hard masks (e.g., two hard masks), the first hard mask for patterning the memory cell or sensor and the second hard mask for patterning the first hard mask. Use of two different masks improves the patterning process control capabilities and widens the process operation windows. While the present disclosure is not so limited, an appreciation of various aspects of the disclosure will be gained through a discussion of the Figures and the examples provided below.

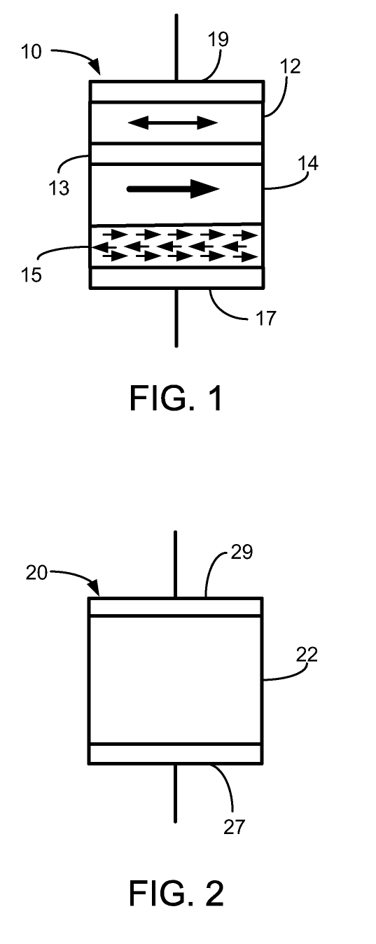

FIG. 1 is a cross-sectional schematic diagram of an illustrative magnetic element or cell. Cell 10 of FIG. 1 may be referred to as a magnetic tunnel junction cell, variable resistive memory cell, resistive sense memory (RSM) cell, or the like. Magnetic cell 10 includes a soft ferromagnetic free layer 12 and a ferromagnetic reference (i.e., pinned) layer 14. Ferromagnetic free layer 12 and ferromagnetic reference layer 14 are separated by an oxide barrier layer 13 or non-magnetic tunnel barrier. Proximate reference layer 14 is an antiferromagnetic (AFM) pinning layer 15, which pins the magnetization orientation of reference layer 14 by exchange bias with the antiferromagnetically ordered material of pinning layer 15. Examples of suitable pinning materials include PtMn, IrMn and others. In other embodiments, reference layer 14 may be pinned by alternate means. Note that other layers, such as seed or capping layers, are not depicted for clarity but could be included as technical need arises.

Ferromagnetic layers 12, 14 may be made of any useful ferromagnetic (FM) material such as, for example, Fe, Co or Ni and alloys thereof, such as NiFe and CoFe. Ternary alloys, such as CoFeB, may be particularly useful because of their lower moment and high polarization ratio, which are desirable for the spin-current switch. Either or both of free layer 12 and reference layer 14 may be either a single ferromagnetic layer or a synthetic antiferromagnetic (SAF) coupled structure, i.e., two ferromagnetic sublayers separated by a metallic spacer, such as Ru or Cu, with the magnetization orientations of the sublayers in opposite directions to provide a net magnetization. The magnetization orientation of ferromagnetic free layer 12 is more readily switchable than the magnetization orientation of ferromagnetic reference layer 14. Either or both layer 12, 14 are often about 0.1-10 nm thick, depending on the material and the desired resistance and switchability of free layer 12.

Barrier layer 13 may be made of an electrically insulating material such as, for example an oxide material (e.g., Al₂O₃, TiOₓ or MgO). Other suitable materials may also be used. Barrier layer 13 could optionally be patterned with free layer 12 or with reference layer 14, depending on process feasibility and device reliability.

A first or bottom electrode 17 is in electrical contact with AFM pinned layer 15 and with reference layer 14 and a second or top electrode 19 is in electrical contact with free layer 12. Electrodes 18, 19 electrically connect ferromagnetic layers 12, 14 to a control circuit providing read and write currents through layers 12, 14.

The resistance across magnetic cell 10 is determined by the relative orientation of the magnetization vectors or magnetization orientations of ferromagnetic layers 12, 14. The magnetization direction of ferromagnetic reference layer 14 is pinned in a predetermined direction (e.g., by pinning layer 15) while the magnetization direction of ferromagnetic free layer 12 is free to rotate under the influence of spin torque.

In FIG. 1, the magnetization orientation of free layer 12 is illustrated as undefined. Magnetic memory cell 10 is in the low resistance state when the magnetization orientation of free layer 12 is in the same direction (parallel) as the magnetization orientation of reference layer 14. Conversely, a magnetic memory cell is in the high resistance state when the magnetization orientation of free layer 12 is in the opposite direction (anti-parallel) of the magnetization orientation of reference layer 14. Switching the resistance state and hence the data state of magnetic cell 10 via spin-transfer occurs when a current, passing through a magnetic layer of magnetic cell 10, becomes spin polarized and imparts a spin torque on free layer 12. When a sufficient spin torque is applied to free layer 12, the magnetization orientation of free layer 12 can be switched between two opposite directions and accordingly, magnetic cell 10 can be switched between the low resistance state and the high resistance state.

The magnetization orientations of free layer 12 and reference layer 14 of magnetic memory cell 10 are in the plane of the layers, or “in-plane”. In other embodiments, the magnetization orientations of the free layer and the pinned layer may be perpendicular to the plane of the layers, or “out-of-plane”.

As indicated above, memory cell 10 is illustrated with undefined magnetization orientation for free layer 12. Also as indicated above, a magnetic memory cell is in the low resistance state when the magnetization orientation of free layer 12 is in the same direction as the magnetization orientation of reference layer 14. Conversely, a magnetic memory cell is in the high resistance state when the magnetization orientation of free layer 12 is in the opposite direction of the magnetization orientation of reference layer 14. In some embodiments, the low resistance state is the “1” data state and the high resistance state is the “1” data state, whereas in other embodiments, the low resistance state is “1” and the high resistance state is “0”.

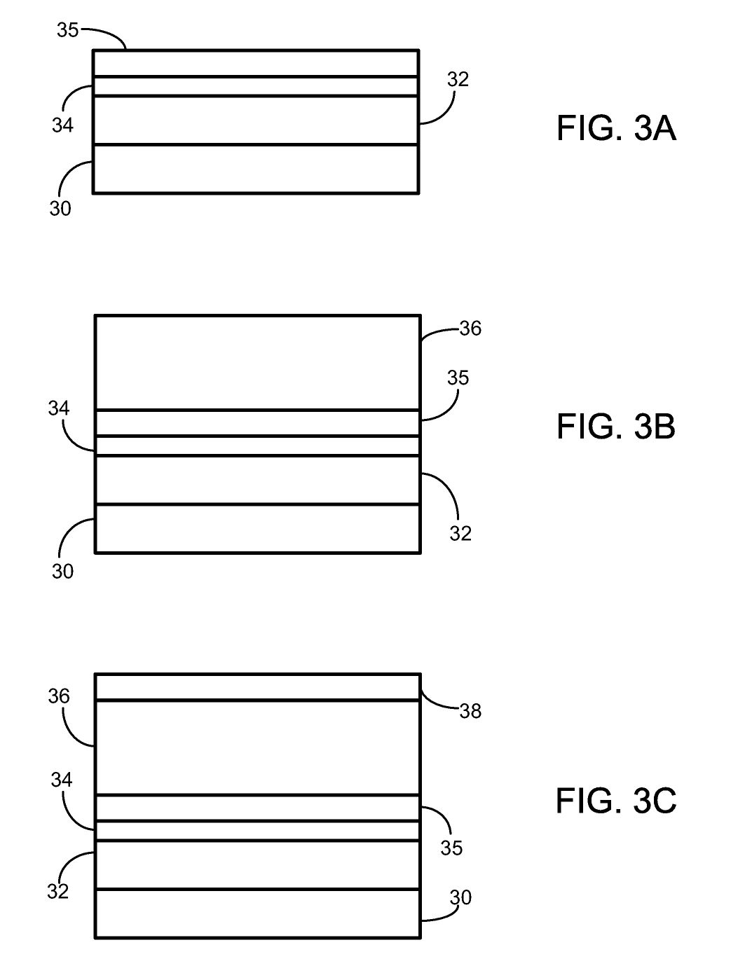

Another RSM cell is resistive cell 20 of FIG. 2 that has a layer 22 with variable resistance. A first electrode 27 is in electrical contact with a first side of layer 22 and a second electrode 29 is in electrical contact with a second side of layer 22. Other layers, such as seed or capping layers, are not depicted for clarity. Electrodes 27, 29 provide a current or voltage through layer 22, which alters the resistance of layer 22. The resistance of layer 22 may alter, for example, by the creation of conductive filaments, fibrils or superionic clusters from electrode 27 to electrode 29 through layer 22. In other embodiments, layer 22 may change phase (i.e., from amorphous to crystalline) and thus change resistance. Electrodes 27, 29 also electrically connect layer 22 to a control circuit providing read and write currents through layer 22. In some embodiments, resistive cell 20 is in the low resistance state or “0” data state. In other embodiments, resistive cell 20 is in the high resistance state or “1” data state.

The present disclosure provides a method for making cells 10, 20 by utilizing a multiple hard mask approach. By using the multiple hard masks and etch stop layer(s), the patterning process control capabilities can be improved, the process operation windows can be widened, and cell sizes and shapes can be optimized.

Patterning of the cell (e.g., memory cell, sensor, etc.) is an important step for RSM and magnetic sensor developments. Because metals used to grow the magnetic or resistive stack (e.g., a magnetic tunnel junction cell for STRAM) are very reactive to the chemicals used in etching processes, processes such as reactive ion etch (RIE) that use chlorine and/or fluorine, stack corrosion often happens when RIE used to pattern the stack. By using the multiple hard masks and etch stop layer(s) with a physical patterning process, such as ion beam etch (IBE), corrosion is inhibited; this is particularly suited for STRAM memory cells. Additionally, by using the multiple hard masks, the physical patterning process (e.g., IBE) can be used to remove hard-to-etch materials; this is particularly suited for RRAM memory cells.

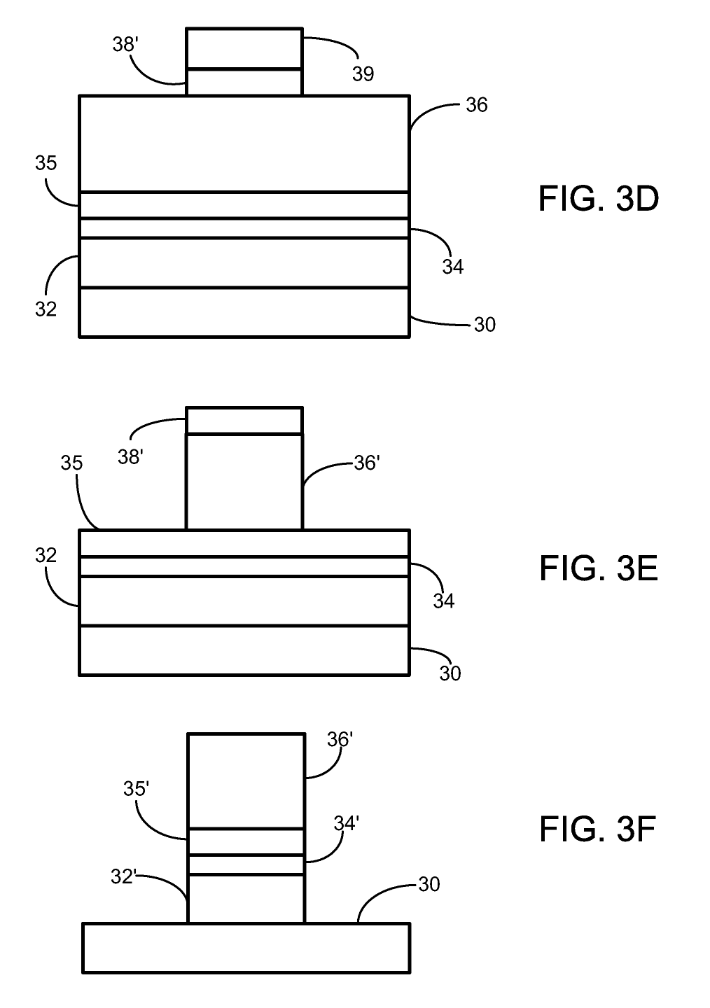

The patterning process can be accomplished by several process integration sequences, one of which are briefly explained below in respect to FIGS. 3A-3F. Overall, the various features or layers of the cells of this disclosure may be made by thin film techniques such as chemical vapor deposition (CVD), physical vapor deposition (PVD), atomic layer deposition (ALD), photolithography, or other thin film deposition techniques. Removal of material may be done by thin film techniques such as wet or dry etching, ion milling, ion beam etch (IBE), inductive coupled plasma (ICP), reactive ion etching (RIE) or other thin film removal techniques, unless stated otherwise.

In FIG. 3A, an initial stack of substrate 30 (e.g., a Si wafer), memory or sensor stack layer 32, an adhesion layer 34, and an etch stop layer 35 are provided. Memory or sensor stack layer 32 may be any functional stack, such as a magnetic memory cell (e.g., cell 10), a resistive cell (e.g., cell 20) or a magnetic sensor. Included in layer 32 is a bottom electrode (e.g., electrode 17 or 27) and the stack functional layers (e.g., free layer 12, reference layer 14 and barrier layer 13 or variable resistance layer 22). In most embodiments, functional layer 32 has a thickness of about 1-100 nm. Adhesion layer 34, if present, facilitates the application of and improves the adhesion of etch stop layer 35 onto functional layer 32. An example of a suitable adhesion layer 34 is Ti, at a thickness of about 20-100 Å, in some embodiments, about 50 Å. Other suitable materials for adhesion layer 34 include metals such as Ta, Cu, Ni, W and Pt. In some embodiments, an organic or inorganic bottom antireflective coating (BARC) layer may be provided between functional layer 32 and adhesion layer 34. Over layer 22 and optional adhesion layer 34 is etch stop layer 35. An example of a suitable etch stop layer 35 is W, at a thickness of about 50-500 Å, in some embodiments, about 250 Å. Other suitable materials for etch stop layer 35 include metals such as Ta, Ru, Pt, TiW and TaN. In some embodiments, adhesion layer 34 and etch stop layer 35 are formed as a single layer, for example, of TiW, at a thickness of about 25-500 Å, in some embodiments, about 250 Å. In some embodiments, both etch stop layer 35 and adhesion layer 34, whether individual layers or combined, are electrically conductive.

A first hard mask 36 is applied (e.g., deposited) over etch stop layer 35 in FIG. 3B. In some embodiments, hard mask 36 is applied directly onto etch stop layer 35, so that there are no intervening layers. First hard mask 36 is an electrically conductive layer, such as a metal layer. Examples of suitable materials for first hard mask 36 include TiN, Ta, TaN, W, Ti and TiW. The thickness of first hard mask 36 is, for example, about 100-3000 Å (10-300 nm), in some embodiments, about 2000 Å (200 nm). As another example, first hard mask 36 may be about 100-1000 Å (10-100 nm) thick. In the final cell, hard mask 36 may be the top electrode (e.g., electrode 19, 29), thus eliminating the need for a separate electrode layer.

A second hard mask 38 is applied (e.g., deposited) on top of first hard mask 36 in FIG. 3C. In some embodiments, there are no intervening layers between first hard mask 36 and second hard mask 38. Second hard mask 38 is a hard mask for patterning first hard mask 36, particularly when hard mask 36 will eventually be used as the top electrode. The material of second hard mask 38 is different than the material of first hard mask 36. Examples of suitable materials for second hard mask 38 include dielectric materials such as SiO₂, Si₃N₄, SiOₓN_{y} and amorphous carbon. The thickness of second hard mask 38 is less than the thickness of first hard mask 36; in some embodiments, first hard mask 36 is at least twice as thick as second hard mask 38, in other embodiments, at least three times as thick. The thickness of second hard mask 38 is, for example, about 100-1000 Å (10-100 nm), in some embodiments, about 500 Å (50 nm).

A photo resist 39 is used to pattern second hard mask 38 to form a hard mask 38′ in FIG. 3D having an area less than its original area. Generally, reduced hard mask 38′ has a diameter less than or equal to 100 nm, in some embodiments less than or equal to 65 nm and in some embodiments less than or equal to 45 nm. Depending on the subsequent etching process, photo resist 39 may be stripped off or remain on top of the reduced second hard mask 38′ during later patterning of first hard mask 36. For the following discussion, photo resist 39 is stripped off of reduced second hard mask 38′ after hard mask 38 has been patterned.

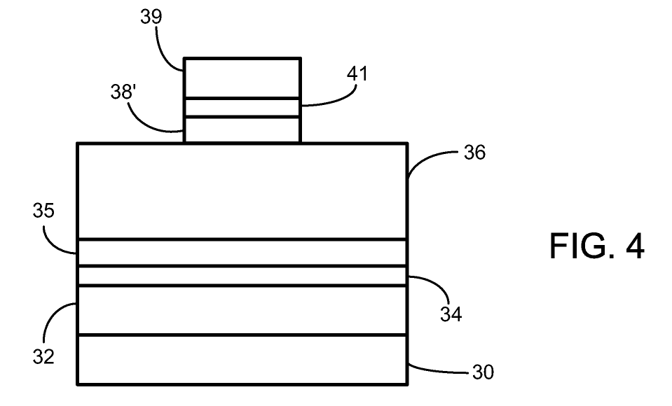

In some embodiments, depending on the specific materials used for photo resist 39 and second hard mask 38, 38′, reflective patterning issues may occur. To inhibit the reflective patterning, an organic or inorganic antireflective coating (ARC) may be provided between second hard mask 38, 38′ and photo resist 39. See FIG. 4, where an ARC coating layer 41 is illustrated between photo resist 39 and second hard mask 38′. When ARC coating 41 is present, an additional patterning of the ARC coating would be done. As an alternate method to inhibit reflective patterning, SiOₓN_{y} is used as second hard mask 38, 38′, with the SiOₓN_{y} having specific film properties that minimize lithography reflections.

Patterned second hard mask 38′, from FIG. 3D, serves as a hard mask for patterning of first hard mask 36 in FIG. 3E. The etching to pattern first hard mask 36 to form reduced first hard mask 36, also to a dimension of less than or equal to 100 nm, in some embodiments less than or equal to 65 nm and in some embodiments less than or equal to 45 nm, stops at etch stop layer 35. Because second hard mask 38, 38′ is relatively thin compared to first hard mask 36, 36′, the topography effects of the first etched pattern upon the second photo exposure's focus margin are relatively low and generally within the process window control. Transferring this thin pattern into the thicker first hard mask 36 allows more process margin during the etch of subsequent layers (e.g., etch stop layer 35, adhesion layer 34, layer 32).

Physical etching processes, such as ion beam etch (IBE) or reactive ion etch (RIE), can be used to etch through etch stop layer 35, adhesion layer 34 and functional layer 32 in FIG. 3F, usually in one process, to form etch stop layer 35′, adhesion layer 34′ and functional layer 32′. If IBE is used, second hard mask 38′ protects first hard mask 36′ and reduces areal loss of first hard mask 36′. In some embodiments, a minimal amount of substrate 30 may be removed by the etching process. After this final etching to pattern functional layer 32′, the resulting structure is that of FIG. 3F. The resulting structure will have the dimensions (e.g., diameter) of etch stop layer 35′, adhesion layer 34′ and functional layer 32′ essentially the same as, or the same as, the dimensions of second hard mask 38′, which are generally no greater in diameter than 100 nm, in some embodiments less than or equal to 65 nm and in some embodiments less than or equal to 45 nm.

As indicated above, the processes of this disclosure, which utilize multiple hard masks, have various benefits to processes that use only a single hard mask. For embodiments where the first (lower) hard mask (e.g., hard mask 36) is the top lead (e.g., electrode 19, 29 of FIGS. 1, 2) in the resulting cell (e.g., cell 10, 20 of FIGS. 1 and 2), the second (upper) hard mask (e.g., hard mask 38) provides accurate patterning of the lower hard mask and the lead. With a single hard mask, it is difficult, if not impossible, to pattern the top lead using only one hard mask due to the small dimensions (i.e., less than 100 nm). At these small dimensions, there is a resist margin issue if only one hard mask is used; that is, the photo resist will be depleted before the etching of the single hard mask is completed, thus resulting in an imprecise, inaccurate edge at these dimensions. For embodiments where the resulting cell is a STRAM cell (e.g., cell 10 of FIG. 1), the use of two separate hard masks with a physical patterning process, such as ion beam etch (IBE), corrosion of the memory layers (e.g., free layer, reference layer, etc.) is inhibited by eliminating the use of chemical etching of the memory layers. For embodiments where the resulting cell is a RRAM cell (e.g., cell 20 of FIG. 2), the use of two separate hard masks, together with a physical patterning process (e.g., IBE), allows removal of hard-to-etch materials that might be present in the variable resistive layer (e.g., layer 22 of FIG. 2).

Thus, embodiments of the CELL PATTERNING WITH MULTIPLE HARD MASKS are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A method of making a cell, comprising:
forming a starting stack comprising a substrate, a functional layer, an etch stop layer, a first hard mask and a second hard mask, with the functional layer between the substrate and the etch stop layer and the first hard mask between the etch stop layer and the second hard mask, on a side opposite the functional layer;
patterning the second hard mask to form a reduced second hard mask, with the first hard mask being a first etch stop for the patterning process;
patterning the first hard mask to form a reduced first hard mask by using the reduced second hard mask as a first mask and using the etch stop layer as a second etch stop; and
patterning the functional layer by using the reduced first hard mask as a second mask.

2. The method of claim 1 wherein the first hard mask comprises metal and the second hard mask comprises dielectric material.

3. The method of claim 2 wherein the first hard mask comprises TiN and the second hard mask comprises SiO₂, Si₃N₄, SiOₓN_{y}, or amorphous carbon.

4. The method of claim 1 wherein the first hard mask has a thickness of about 100-3000 Å and the second hard mask has a thickness of about 100-1000 Å.

5. The method of claim 1 wherein the first hard mask has a thickness at least twice a thickness of the second hard mask.

6. The method of claim 1 wherein the etch stop layer comprises W.

7. The method of claim 1 wherein there are no intervening layers between the etch stop and the first hard mask, and between the first hard mask and the second hard mask.

8. The method of claim 1 wherein patterning the functional layer comprises patterning with ion beam etching (IBE).

9. The method of claim 1 wherein:
patterning the first hard mask to form a reduced first hard mask comprises patterning with ion beam etching (IBE); and
patterning the second hard mask to form a reduced second hard mask comprises patterning with ion beam etching (IBE).

10. The method of claim 1 wherein the cell has a diameter less than or equal to 100 nm.

11. The method of claim 10 wherein the cell has a diameter less than or equal to 65 nm.

12. The method of claim 1 wherein the functional layer comprises a variable resistance material.

13. The method of claim 1 wherein the functional layer comprises a ferromagnetic free layer, a ferromagnetic pinned reference layer and a barrier layer therebetween.

14. The method of claim 1 wherein the functional layer comprises a magnetic material and the magnetic material is a magnetic read sensor in a recording head.

15. The method of claim 1 wherein patterning the second hard mask comprises forming an antireflective coating (ARC) layer between the second hard mask and a photo resist.

16. A method of making a cell, comprising:
forming a starting stack comprising a substrate, a functional layer, an etch stop layer, a metal hard mask and a dielectric hard mask, with the functional layer between the substrate and the etch stop layer and the metal hard mask between the etch stop layer and the dielectric hard mask, on a side opposite the functional layer;
patterning the dielectric hard mask with a first etch step, with the metal hard mask being an etch stop for the patterning process;
patterning the metal hard mask with a second etch step subsequent to the first etch step, with the etch stop layer being an etch stop for the patterning process; and
patterning the functional layer with a third etch step subsequent to the second etch step.

17. The method of claim 16 wherein the first etch step and the second etch step comprise ion beam etching (IBE).

18. A resistive sense memory cell comprising:
a bottom lead;
a memory layer for storing more than one magnetic or resistive state;
an etch stop layer, with the memory layer between the etch stop layer and the bottom lead;
an adhesion layer between the etch stop layer and the memory layer; and
a hard mask layer on the etch stop layer opposite the adhesion layer, wherein the hard mask layer is also a top lead; and
wherein a diameter of the hard mask layer is at least essentially the same as a diameter of the etch stop layer, the adhesion layer, and the memory layer.

19. The resistive sense memory cell of claim 18 wherein the etch stop layer and the adhesion layer are a single layer comprising TiW.

20. The resistive sense memory cell of claim 18 wherein the cell has a diameter less than or equal to 65 nm.
